(19) United States
(12) Patent Application Publication
(10) Pub. No.: US 2025/0191894 A1
(43) Pub. Date: Jun. 12, 2025

(54) SUBSTRATE TREATING APPARATUS AND MANUFACTURING METHOD THEREOF

(71) Applicant: SEMES CO., LTD., Cheonan-si (KR)

(72) Inventors: Jin Il SUNG, Gyeonggi-do (KR); Sun Il KIM, Chungcheongnam-do (KR); Dong Mok LEE, Chungcheongnam-do (KR)

(73) Assignee: SEMES CO., LTD., Cheonan-si (KR)

(21) Appl. No.: 18/914,595

(22) Filed: Oct. 14, 2024

(30) Foreign Application Priority Data
Dec. 8, 2023 (KR) 10-2023-0177240

(51) Int. Cl. H01J 37/32; C23C 28/04

(52) U.S. Cl. CPC H01J 37/32715; C23C 28/042; H01J 2237/334

(57) ABSTRACT

A manufacturing method of a substrate treating apparatus includes: preparing a body having a lower end provided at a first level, having a step formed at a second level higher than the first level, and having an upper end provided at a third level higher than the second level; forming a first coating layer from the first level to a height of a fourth level higher than the third level by a thermal spray coating (TSC) method so as to surround the body; forming a bonding unit from an upper surface of the body to the fourth level; forming a second coating layer on the first coating layer, the second coating layer having a smaller thickness than the bonding unit and higher hardness than the first coating layer; and providing a puck on upper surfaces of the bonding unit and the second coating layer.

### CROSS-REFERENCE TO RELATED APPLICATION

This application claims priority from Korean Patent Application No. 10-2023-0177240 filed on Dec. 8, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a substrate treating apparatus and a manufacturing method thereof.

### 2. Description of the Related Art

A process of manufacturing a semiconductor may include a deposition process for forming a film on a semiconductor wafer (hereinafter referred to as a substrate), a chemical mechanical polishing process for planarizing the film, a photolithography process for forming a photoresist pattern on the film, an etching process for forming the film as a pattern having electrical characteristics using the photoresist pattern, an ion implantation process for implanting specific ions into a predetermined region of the substrate, a cleaning process for removing impurities on the substrate, an inspection process for inspecting a surface of the substrate on which the film or the pattern is formed, and the like.

The etching process is a process for removing an exposed region of the photoresist pattern formed on the substrate by the photolithography process. A type of the etching process may be divided into a dry etching process and wet etching process.

The dry etching process applies high-frequency power to an upper electrode and a lower electrode installed to be spaced apart from each other by a predetermined interval in a closed internal space where the dry etching process is performed to form an electric field, applies the electric field to a reaction gas supplied into the closed internal space to activate the reaction gas and make the reaction gas a plasma state, and then allows ions in plasma to etch the substrate positioned on the lower electrode.

In this case, it is necessary to uniformly form plasma over the entire upper surface of the substrate. A ring assembly may be provided in order to uniformly form the plasma over the entire upper surface of the substrate. The ring assembly is installed to surround an edge of a support unit supporting the substrate.

However, the support unit and the ring assembly are separate components, and thus, there is a gap between the support unit and the ring assembly. Accordingly, in a process in which the etching process is performed, a bonding unit (adhesive layer) of the support unit and a band surrounding the bonding unit and made of an elastic material may be easily etched.

That is, when the band is not provided, the bonding unit is directly etched in the etching process, and even though the band is provided, the band is etched in the etching process, such that the bonding unit is exposed. The exposed bonding unit is etched by reacting with a fluorine gas. When the bonding unit is etched, cooling efficiency decreases, such that temperature unevenness of the support unit may occur. In this case, an etching trend of an edge region of the substrate is changed, such that problems such as a substrate yield defect, shortening of a lifespan of the support unit, and an increase in equipment operating cost due to shortening of a preventive maintenance (PM) cycle occur.

### SUMMARY

Aspects of the present disclosure provide a substrate treating apparatus in which etching of a support unit may be minimized, and a manufacturing method thereof.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a manufacturing method of a substrate treating apparatus includes: preparing a body having a lower end provided at a first level, having a step formed at a second level higher than the first level, and having an upper end provided at a third level higher than the second level; forming a first coating layer from the first level to a height of a fourth level higher than the third level by a thermal spray coating (TSC) method so as to surround the body; forming a bonding unit from an upper surface of the body to the fourth level; forming a second coating layer on the first coating layer, the second coating layer having a smaller thickness than the bonding unit and higher hardness than the first coating layer; and providing a puck on upper surfaces of the bonding unit and the second coating layer.

According to another aspect of the present disclosure, a substrate treating apparatus includes: a chamber having a treating space in which a process of plasma-etching a substrate is performed; a support unit supporting the substrate in the treating space; and a gas supply unit supplying a process gas for plasma-etching the substrate to the treating space, wherein the support unit includes: a body having a lower end provided at a first level, having a step formed at a second level higher than the first level, having an upper end provided at a third level higher than the second level, and made of aluminum; a first coating layer formed from the first level to a height of a fourth level higher than the third level so as to surround the body; a bonding unit formed from an upper surface of the body to the fourth level; a second coating layer provided on the first coating layer and having a smaller thickness than the bonding unit and higher hardness than the first coating layer; a puck provided on upper surfaces of the bonding unit and the second coating layer; and a third coating layer provided from a step of the first coating layer formed along the step of the body to an upper end of the puck.

According to still another aspect of the present disclosure, a substrate treating apparatus includes: a chamber having a treating space in which a process of plasma-etching a substrate is performed; a support unit supporting the substrate in the treating space; and a gas supply unit supplying a process gas for plasma-etching the substrate to the treating space, wherein the support unit includes: a body having a lower end provided at a first level, having a step formed at a second level higher than the first level, having an upper end provided at a third level higher than the second level, made of aluminum, and including a first circulation flow passage through which a heat transfer medium circulates and a second circulation flow passage through which a cooling fluid circulates; a first coating layer formed from the first level to a height of a fourth level higher than the third level so as to surround the body and provided by a thermal spray coating (TSC) method of a ceramic material; a bonding unit formed from an upper surface of the body to the fourth level and made of silicon; a second coating layer provided on the first coating layer and provided by atomic layer deposition (ALD) of at least one of aluminum oxide (Al₂O₃) and yttrium oxide (Y₂O₃) so as to have a smaller thickness than the bonding unit and higher hardness and density than the first coating layer; a puck provided on upper surfaces of the bonding unit and the second coating layer, made of a ceramic material, and having the same radius as the first coating layer; and a third coating layer provided from a step of the first coating layer formed along the step of the body to an upper end of the puck, having the same hardness and density as the second coating layer, and provided by atomic layer deposition (ALD).

Detailed contents of other embodiments are described in a detailed description and are illustrated in the drawings.

With a substrate treating apparatus and a manufacturing method thereof according to the present disclosure, etching of a support unit may be minimized, such that a substrate yield defect may be decreased and a lifespan of the support unit may be increased.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a substrate treating apparatus according to a first exemplary embodiment of the present disclosure;

FIG. 2 is a view illustrating region A of FIG. 1;

FIG. 3 is a view illustrating a support unit of a substrate treating apparatus according to a second exemplary embodiment of the present disclosure;

FIG. 4 is a flowchart for describing a manufacturing method of a substrate treating apparatus according to some exemplary embodiments of the present disclosure;

FIG. 5 is a view illustrating a state in which a body of the substrate treating apparatus according to some exemplary embodiments of the present disclosure is provided;

FIG. 6 is a view illustrating a state in which a first coating layer of the substrate treating apparatus according to some exemplary embodiments of the present disclosure is formed at a perimeter of the body;

FIG. 7 is a view illustrating a state in which a bonding unit of the substrate treating apparatus according to some exemplary embodiments of the present disclosure is provided on the body;

FIG. 8 is a view illustrating a state in which a second coating layer of the substrate treating apparatus according to some exemplary embodiments of the present disclosure is provided on the first coating layer;

FIG. 9 is a view illustrating a state in which a puck of the substrate treating apparatus according to some exemplary embodiments of the present disclosure is provided on the bonding unit; and

FIG. 10 is a view illustrating a state in which a third coating layer of the substrate treating apparatus according to some exemplary embodiments of the present disclosure is provided at a perimeter of the first coating layer.

### DETAILED DESCRIPTION OF THE EMBODIMENTS

Hereinafter, exemplary embodiments of the present disclosure will be described in detail with reference to the accompanying drawings. Advantages and features of the present disclosure and methods for accomplishing these advantages and features will become apparent from exemplary embodiments to be described later in detail with reference to the accompanying drawings. However, the present disclosure is not limited to exemplary embodiments to be disclosed below, and may be implemented in various different forms, these exemplary embodiments will be provided only in order to make the present disclosure complete and allow one of ordinary skill in the art to which the present disclosure pertains to completely recognize the scope of the present disclosure, and the present disclosure will be defined by the scope of the claims. Throughout the specification, the same components will be denoted by the same reference numerals.

The terms as used herein are for describing exemplary embodiments rather than limiting the present disclosure. In the present specification, a singular form includes a plural form unless stated otherwise in the phrase. The terms “comprise” and/or “comprising” as used herein do not exclude the existence or addition of one or more other components, steps, operations, and/or elements in addition to the mentioned components, steps, operations, and/or elements.

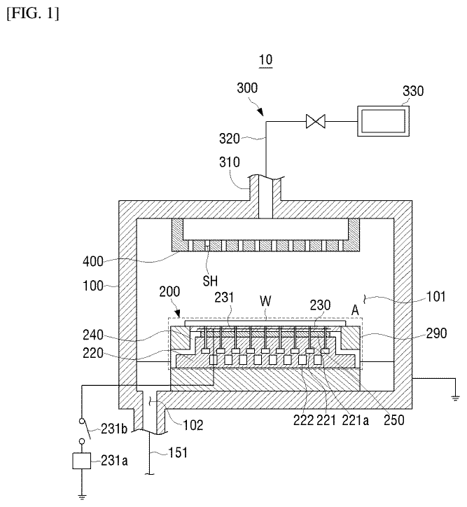

FIG. 1 is a view illustrating a substrate treating apparatus according to a first exemplary embodiment of the present disclosure.

Referring to FIG. 1, a substrate treating apparatus 10 according to an exemplary embodiment of the present disclosure may include a chamber 100, a support unit 200, a gas supply unit 300, and a shower head 400. The substrate treating apparatus 10 may treat a substrate W using plasma. As an example, the substrate treating apparatus 10 may perform an etching process on the substrate W.

In addition, as the substrate treating apparatus 10 according to the present exemplary embodiment, both a capacitively coupled plasma (CCP)-type substrate treating apparatus and an inductively coupled plasma (ICP)-type substrate treating apparatus may be applied. That is, the CCP-type substrate treating apparatus will hereinafter be described as an example of the substrate treating apparatus 10, but the present disclosure is not limited thereto, and various modified examples such as a modified example in which the ICP-type substrate treating apparatus is applied are possible.

In addition, the capacitively coupled plasma (CCP)-type substrate treating apparatus may include an upper electrode and a lower electrode inside the chamber 100. The upper electrode and the lower electrode may be disposed above and below in parallel with each other inside the chamber 100. Any one of the upper electrode and the lower electrode may apply high-frequency power, and the other of the upper electrode and the lower electrode may be grounded. An electromagnetic field is formed in a space between the upper electrode and the lower electrode, and a process gas supplied to a substrate treating space, which is the space between the upper electrode and the lower electrode, may be excited into a plasma state. In the present exemplary embodiment, the upper electrode may be the shower head 400 and the lower electrode may be a body 220, but the present disclosure is not limited thereto.

The chamber 100 may be implemented as a plasma reaction chamber etching the substrate W, and may provide a treating space 101 in which a substrate treating process is performed inside. As an example, the chamber 100 may have a cylindrical shape. The chamber 100 may be provided in a shape in which the treating space 101 is closed. The chamber 100 may be made of a metal material such as aluminum, and may be grounded.

An exhaust hole 102 may be formed in a bottom surface of the chamber 100. The exhaust hole 102 may be connected to an exhaust line 151. A reaction byproduct generated in a process and a gas remaining in an internal space of the chamber 100 may be exhausted to the outside through the exhaust hole 102 and the exhaust line 151. The inside of the chamber 100 may be decompressed to a predetermined pressure by an exhaust process, and for example, a vacuum atmosphere may be formed inside the chamber 100.

The support unit 200 may be positioned inside the chamber 100. The support unit 200 may support the substrate W. The support unit 200 may be provided as an electrostatic chuck adsorbing the substrate W using electrostatic force. Alternatively, the support unit 200 may support the substrate W by various methods such as mechanical clamping. Hereinafter, a case where the support unit 200 is provided as the electrostatic chuck will be described by way of example.

As an example, the support unit 200 may include the body 220, a puck 230, and a ring assembly 290.

The puck 230 may be positioned above the body 220. The body 220 may be made of a metal material such as aluminum, and may perform a function of the lower electrode. An upper surface of the body 220 may have a step formed so that a center region thereof is positioned higher than an edge region thereof. The center region of the upper surface of the body 220 may have an area corresponding to a lower surface of the puck 230. That is, the center region of the upper surface of the body 220 and the lower surface of the puck 230 may have the same area and the same diameter. In addition, the body 220 may be bonded to the lower surface of the puck 230 by a bonding unit 250.

The body 220 may be electrically connected to a separate power source (not illustrated). The power source connected to the body 220 may be provided as a high-frequency power source generating high-frequency power such as RF (high-voltage alternating current power). The body 220 receiving the high-frequency power applied from the power source may function as an electrode.

In addition, a first circulation flow passage 221, a first supply flow passage 221a, and a second circulation flow passage 222 may be formed inside the body 220.

The first circulation flow passage 221 may be provided as a passage through which a heat transfer medium circulates. As an example, the first circulation flow passage 221 may be formed in a spiral shape inside the body 220. As another example, the first circulation flow passages 221 may be disposed so that flow passages having ring shapes with different radii have the same center, and the respective first circulation flow passages 221 may be in communication with each other. The first circulation flow passages 221 may be formed at the same height.

The first circulation flow passage 221 may be connected to a heat transfer medium storage portion (not illustrated) through a heat transfer medium supply line (not illustrated). The heat transfer medium may be stored in the heat transfer medium storage portion. The heat transfer medium may be an inert gas such as a helium gas. The helium gas may be supplied to the first circulation flow passage 221 through the heat transfer medium supply line. The helium gas passing through the first circulation flow passage 221 may serve as a medium transferring heat of the substrate W. That is, the substrate W may be cooled by the helium gas.

A plurality of first supply flow passages 221a may be provided, and may extend upward from the first circulation flow passages 221. For example, the first supply flow passage 221a may penetrate through the body 220 and the puck 230 and supply the heat transfer medium to a lower surface of the substrate W. In addition, the first supply flow passage 221a and the first circulation flow passage 221 may be provided as flow passages recovering the heat transfer medium after the etching of the substrate W is completed.

That is, after the helium gas is supplied to the lower surface of the substrate W through the first circulation flow passage 221 and the first supply flow passage 221a, the helium gas may be recovered to the heat transfer medium storage portion through the first supply flow passage 221a and the first circulation flow passage 221, but the present disclosure is not limited thereto.

The second circulation flow passage 222 may be provided as a passage through which a cooling fluid (e.g., a coolant) circulates. The second circulation flow passage 222 may be formed in a spiral shape inside the body 220. Alternatively, the second circulation flow passages 222 may be disposed so that flow passages having ring shapes with different radii have the same center. The respective second circulation flow passages 222 may be in communication with each other. The second circulation flow passage 222 may have a greater cross-sectional area than the first circulation flow passage 221. The second circulation flow passage 222 may be positioned below the first circulation flow passage 221.

The second circulation flow passage 222 may be connected to a cooling fluid storage portion (not illustrated) through a cooling fluid supply line (not illustrated). The cooling fluid may be stored in the cooling fluid storage portion. A cooler (not illustrated) may be provided within the cooling fluid storage portion. The cooler may cool the cooling fluid to a predetermined temperature. Alternatively, the cooler may be installed on the cooling fluid supply line. The cooling fluid supplied to the second circulation flow passage 222 through the cooling fluid supply line may cool the body 220 while circulating along the second circulation flow passage 222. The body 220 may maintain the substrate W at a predetermined temperature by cooling the puck 230 and the substrate W together while being cooled.

The puck 230 may be positioned at an upper end of the body 220. The puck 230 may be provided as a dielectric substance having a disk shape. The substrate W may be put on an upper surface of the puck 230. The upper surface of the puck 230 may have a smaller radius than the substrate W. An edge region of the substrate W may be positioned outside the puck 230. For example, the edge region of the substrate W may be positioned on the ring assembly 290.

In addition, a first electrode 231 may be provided inside the puck 230. The first electrode 231 may be electrically connected to a first power source 231a. The first power source 231a may include a power source. A switch 231b may be installed between the first electrode 231 and the first power source 231a. The first electrode 231 may be electrically connected to the first power source 231a by turn-on/off of the switch 231b. When the switch 231b is turned on, a current may be applied to the first electrode 231. Electrostatic force may act between the first electrode 231 and the substrate W by the current applied to the first electrode 231, and the substrate W may be adsorbed to the puck 230 by the electrostatic force.

The ring assembly 290 may concentrate the plasma on the substrate. Although not illustrated in the drawings, the ring assembly 290 may be provided as a combination of one or more rings. For example, the ring assembly 290 may be provided as an inner ring surrounding the puck 230, an outer ring surrounding the inner ring, and the like.

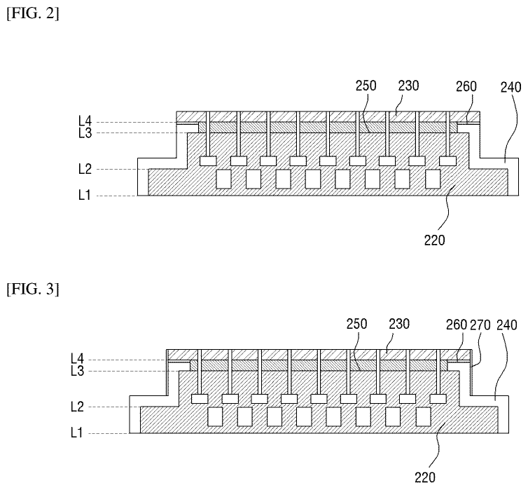

In addition, the support unit 200 according to the present exemplary embodiment may have a structure in which etching is minimized or prevented, which will be described with reference to FIG. 2.

The gas supply unit 300 may supply a process gas (e.g., a gas including fluorine) into the chamber 100. The gas supply unit 300 may include a gas feeder 310, a gas supply pipe 320, and a gas storage portion 330.

The gas of the gas storage portion 330 may be supplied into the chamber 100 through the gas feeder 310 via the gas supply pipe 320. As an example, the gas feeder 310 may be installed at a center portion of an upper surface of the chamber 100.

The shower head 400 may be spaced apart from the upper surface of the chamber 100 downward by a predetermined distance, such that a predetermined space may be formed at an upper portion of the chamber 100. The shower head 400 may be provided in a plate shape having a certain thickness. A plurality of spray holes SH may be formed in the shower head 400. The spray hole SH may penetrate through the shower head 400 in a vertical direction and spray the process gas into the treating space 101.

The shower head 400 may be made of a metal material, and a lower surface of the shower head 400 may be anodized in order to prevent generation of arc by the plasma. The shower head 400 may be electrically connected to a separate power source (not illustrated). The power source of the shower head 400 may be provided as a high-frequency power source (e.g., a high-voltage alternating current power source). Alternatively, the shower head 400 may be electrically grounded. The shower head 400 may be electrically connected to the power source or may be grounded to function as an upper electrode. For example, the shower head 400 may be provided to have a diameter that is the same as or similar to that of the support unit 200.

Hereinafter, the support unit 200 in which etching is minimized or prevented will be described with reference to the drawings, and a description of contents overlapping those described above will be omitted.

FIG. 2 is a view illustrating region A of FIG. 1 (however, the ring assembly 290 is omitted in FIG. 2).

Referring to FIG. 2, the support unit 200 may include the body 220, the puck 230, the bonding unit 250, a first coating layer 240, a second coating layer 260, and the ring assembly 290.

The body 220 may have a lower end provided at a first level L1, and may have a step formed at a second level L2 higher than the first level L1. In addition, the body 220 may have an upper end provided at a third level L3 higher than the second level L2.

The first coating layer 240 may be formed from the first level L1 to a height of a fourth level L4 higher than the third level L3 so as to surround the body 220. Referring to FIG. 2, the second coating layer 260 is positioned at the fourth level L4, but may be formed by an atomic layer deposition (ALD) method to have the form of a thin film. Accordingly, a height of the second coating layer 260 on the first coating layer 240 may form the fourth level L4.

In addition, the first coating layer 240 may be made of a ceramic material, and may be provided by a thermal spray coating (TSC) method, unlike the atomic layer deposition method of forming the second coating layer 260.

The bonding unit 250 may be made of silicon, and may be formed from the upper surface of the body 220 to the fourth level L4. The bonding unit 250 may be bonded to the body 220 and the puck 230. A curing process may be performed on the bonding unit 250, but is not limited thereto.

In addition, it has been illustrated that a radius of the bonding unit 250 according to the present exemplary embodiment is smaller than a radius of the upper surface of the body 220, but the present disclosure is not limited thereto. As another example, various modified examples such as a modified example in which a radius of the bonding unit 250 is the same as a radius of the upper surface of the body 220 are possible.

The second coating layer 260 may be provided on the first coating layer 240, and may have a smaller thickness than the bonding unit 250. The second coating layer 260 may have higher hardness and density than the first coating layer 240. The second coating layer 260 may be formed by the atomic layer deposition method unlike the thermal spray coating method of forming the first coating layer 240. As an example, the second coating layer 260 may be provided by the atomic layer deposition method of aluminum oxide (Al₂O₃) and/or yttrium oxide (Y₂O₃).

The puck 230 may be provided on upper surfaces of the bonding unit 250 and the second coating layer 260. The puck 230 may be made of a ceramic material, and may have the same radius as the first coating layer 240.

Hereinafter, a modified example of the present exemplary embodiment will be described with reference to FIG. 3, and an overlapping description of the same components performing the same functions will be omitted.

FIG. 3 is a view illustrating a support unit of a substrate treating apparatus according to a second exemplary embodiment of the present disclosure. Contents different from those described with reference to FIGS. 1 to 2 will be mainly described with reference to FIG. 3.

Referring to FIG. 3, a support unit 200 according to a second exemplary embodiment may include a body 220, a puck 230, a bonding unit 250, a first coating layer 240, a second coating layer 260, a ring assembly 290, and the like, identically or similarly to the support unit according to a first exemplary embodiment. Meanwhile, the support unit 200 according to a second exemplary embodiment may further include a third coating layer 270.

The third coating layer 270 may be provided from a step of the first coating layer 240 formed along a step of the body 220 to an upper end of the puck 230.

The third coating layer 270 may have hardness and density that are the same as or similar to those the second coating layer 260. That is, the third coating layer 270 and the second coating layer 260 may have higher hardness and density than the first coating layer 240. The third coating layer 270 may be provided by an atomic layer deposition method, identically or similarly to the second coating layer 260. As an example, the third coating layer 270 may be provided by the atomic layer deposition method of aluminum oxide (Al₂O₃) and/or yttrium oxide (Y₂O₃).

Hereinafter, a manufacturing method of a support unit 200 of a substrate treating apparatus 10 will be described with reference to the drawings.

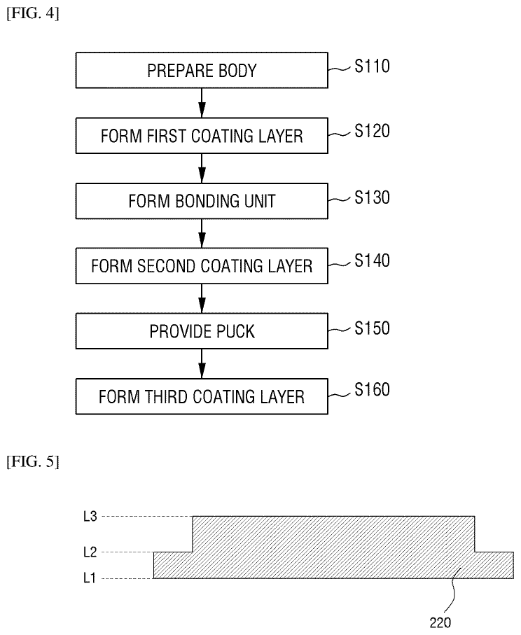

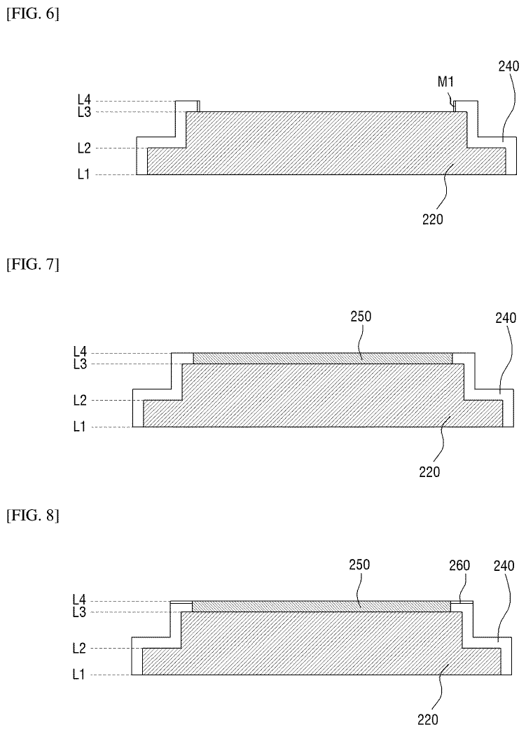

FIG. 4 is a flowchart for describing a manufacturing method of a substrate treating apparatus according to a second exemplary embodiment of the present disclosure. FIG. 5 is a view illustrating a state in which a body of the substrate treating apparatus according to some exemplary embodiments of the present disclosure is provided, FIG. 6 is a view illustrating a state in which a first coating layer of the substrate treating apparatus according to some exemplary embodiments of the present disclosure is formed at a perimeter of the body, and FIG. 7 is a view illustrating a state in which a bonding unit of the substrate treating apparatus according to some exemplary embodiments of the present disclosure is provided on the body.

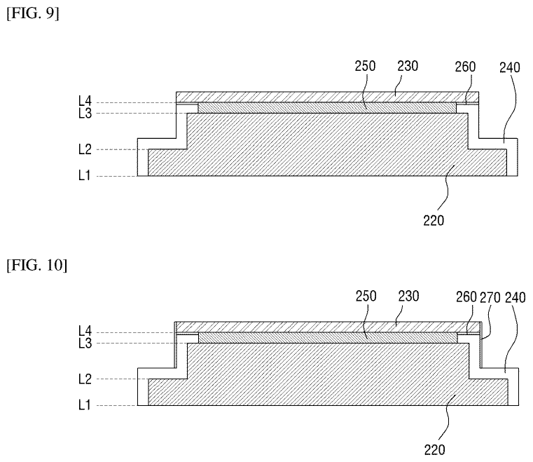

In addition, FIG. 8 is a view illustrating a state in which a second coating layer of the substrate treating apparatus according to some exemplary embodiments of the present disclosure is provided on the first coating layer, FIG. 9 is a view illustrating a state in which a puck of the substrate treating apparatus according to some exemplary embodiments of the present disclosure is provided on the bonding unit, and FIG. 10 is a view illustrating a state in which a third coating layer of the substrate treating apparatus according to some exemplary embodiments of the present disclosure is provided at a perimeter of the first coating layer.

Referring to FIGS. 4 to 10, a manufacturing method of the substrate treating apparatus 10 may include preparing the body 220 (S110), forming the first coating layer 240 (S120), forming the bonding unit 250 (S130), forming the second coating layer 260 (S140), providing the puck 230 (S150), and forming the third coating layer 270 (S160).

First, referring to FIGS. 4 and 5, the body 220 made of aluminum may be prepared. The upper surface of the body 220 may have the step formed so that the center region thereof is positioned higher than the edge region thereof. For example, the body 220 may have the lower end provided at the first level L1, may have the step formed at the second level L2 higher than the first level L1, and may have the upper end provided at the third level L3 higher than the second level L2.

Next, referring to FIGS. 4 and 6, the first coating layer 240 may be formed at a perimeter of the body 220. The first coating layer 240 may be formed by the thermal spray coating method. Here, through the thermal spray coating method, the first coating layer 240 may be formed to have a predetermined thickness required for a design value of the support unit 200. That is, the first coating layer 240 may be formed by melting powders of a material and spray-coating the molten material onto a surface of the body 220.

As an example, a frame M1 corresponding to an outer diameter of the bonding unit 250 may be provided on the upper surface of the body 220. Here, the frame M1 may be formed to a height of the fourth level L4 so that the first coating layer 240 surrounds the bonding unit 250 while surrounding the body 220. That is, the first coating layer 240 may be formed from the first level L1 to the height of the fourth level L4.

After the frame M1 is provided, the first coating layer 240 may be formed by spray-coating the molten material along perimeters of the body 220 and the frame M1. The first coating layer 240 provided by the thermal spray coating method may have lower hardness and density but may have a greater thickness than a coating layer provided by an atomic layer deposition method.

That is, the first coating layer 240 may be provided to have a predetermined thickness by the thermal spray coating method so as to sufficiently cover perimeters of the body 220 and the bonding unit 250. On the other hand, the third coating layer 270 is provided by the atomic layer deposition method so as to have higher hardness than the first coating layer 240 and covers the first coating layer 240. Accordingly, the etching of the first coating layer 240 may be further minimized.

Next, referring to FIGS. 4 and 7, the bonding unit 250 made of silicon may be formed. The bonding unit 250 may be formed from the upper surface of the body 220 to the fourth level L4. The bonding unit 250 is an adhesive layer, and may be provided by applying an adhesive.

Next, referring to FIGS. 4 and 8, the second coating layer 260 having a smaller thickness than the bonding unit 250 may be formed on an upper surface of the first coating layer 240. The second coating layer 260 may be formed by the atomic layer deposition method of aluminum oxide (Al₂O₃) and/or yttrium oxide (Y₂O₃).

The second coating layer 260 may have higher hardness and density and a smaller thickness than the first coating layer 240 provided by the thermal spray coating method. The second coating layer 260 may have a small thickness to easily fill a gap.

That is, the puck 230 having the same radius as the first coating layer 240 is provided on an upper surface of the bonding unit 250, and the first coating layer 240 is provided at the perimeter of the bonding unit 250. However, the first coating layer 240 and the puck 230 are separated structures, and a gap may be formed between the separated structures, and thus, there is a risk that the bonding unit 250 will be etched through the gap. The second coating layer 260 may fill the gap between the first coating layer 240 and the puck 230 so that the bonding unit 250 is not etched through the gap.

That is, in order to compensate for a manufacturing error and/or flatness of the puck 230, the second coating layer 260 may be provided on the first coating layer 240. Here, a lower surface of the puck 230 may be formed to have a predetermined flexure even though the puck 230 is manufactured to be flat, and thus, the second coating layer 260 is provided to fill the gap between the lower surface of the puck 230 and the first coating layer 240 as much as possible.

Next, referring to FIGS. 4 and 9, the puck 230 may be provided on upper surfaces of the bonding unit 250 and the second coating layer 260. The body 220 may be bonded to the puck 230 by the bonding unit 250.

Next, referring to FIGS. 4 and 10, after the puck 230 is provided, the third coating layer 270 may be formed from the step of the first coating layer 240 formed along the step of the body 220 to the upper end of the puck 230.

The third coating layer 270 may be formed by the atomic layer deposition method of aluminum oxide (Al₂O₃) and/or yttrium oxide (Y₂O₃), identically or similarly to the second coating layer 260.

The exemplary embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects.

What is claimed is:

1. A manufacturing method of a substrate treating apparatus, comprising:
preparing a body having a lower end provided at a first level, having a step formed at a second level higher than the first level, and having an upper end provided at a third level higher than the second level;
forming a first coating layer from the first level to a height of a fourth level higher than the third level by a thermal spray coating (TSC) method so as to surround the body;
forming a bonding unit from an upper surface of the body to the fourth level;
forming a second coating layer on the first coating layer, the second coating layer having a smaller thickness than the bonding unit and higher hardness than the first coating layer; and
providing a puck on upper surfaces of the bonding unit and the second coating layer.

2. The manufacturing method of a substrate treating apparatus of claim 1, wherein in the forming of the second coating layer, the second coating layer is formed by an atomic layer deposition (ALD) method.

3. The manufacturing method of a substrate treating apparatus of claim 1, wherein in the forming of the second coating layer, the second coating layer is made of at least one of aluminum oxide (Al₂O₃) and yttrium oxide (Y₂O₃).

4. The manufacturing method of a substrate treating apparatus of claim 1, further comprising, after the providing of the puck, forming a third coating layer from a step of the first coating layer formed along the step of the body to an upper end of the puck.

5. The manufacturing method of a substrate treating apparatus of claim 4, wherein in the forming of the third coating layer, the third coating layer is formed by an atomic layer deposition (ALD) method.

6. The manufacturing method of a substrate treating apparatus of claim 5, wherein in the forming of the third coating layer, the third coating layer is made of at least one of aluminum oxide (Al₂O₃) and yttrium oxide (Y₂O₃).

7. The manufacturing method of a substrate treating apparatus of claim 1, wherein in the preparing of the body, the body is made of aluminum.

8. The manufacturing method of a substrate treating apparatus of claim 1, wherein in the forming of the first coating layer, the first coating layer is made of a ceramic material.

9. The manufacturing method of a substrate treating apparatus of claim 1, wherein in the forming of the bonding unit, the bonding unit is made of silicon.

10. The manufacturing method of a substrate treating apparatus of claim 1, wherein in the providing of the puck, the puck has the same radius as the first coating layer, and is made of a ceramic material.

11. A substrate treating apparatus comprising:
a chamber having a treating space in which a process of plasma-etching a substrate is performed;
a support unit supporting the substrate in the treating space; and
a gas supply unit supplying a process gas for plasma-etching the substrate to the treating space,
wherein the support unit includes:
a body having a lower end provided at a first level, having a step formed at a second level higher than the first level, having an upper end provided at a third level higher than the second level, and made of aluminum;
a first coating layer formed from the first level to a height of a fourth level higher than the third level so as to surround the body;
a bonding unit formed from an upper surface of the body to the fourth level;
a second coating layer provided on the first coating layer and having a smaller thickness than the bonding unit and higher hardness than the first coating layer;
a puck provided on upper surfaces of the bonding unit and the second coating layer; and
a third coating layer provided from a step of the first coating layer formed along the step of the body to an upper end of the puck.

12. The substrate treating apparatus of claim 11, wherein the second coating layer and the third coating layer have the same hardness and density.

13. The substrate treating apparatus of claim 12, wherein the first coating layer provided by thermal spray coating (TSC) of a ceramic material.

14. The substrate treating apparatus of claim 12, wherein each of the second coating layer and the third coating layer is provided by atomic layer deposition (ALD) of at least one of aluminum oxide (Al₂O₃) and yttrium oxide (Y₂O₃).

15. The substrate treating apparatus of claim 11, wherein the bonding unit is made of silicon, and
the puck is made of a ceramic material, and has the same radius as the first coating layer.

16. A substrate treating apparatus comprising:
a chamber having a treating space in which a process of plasma-etching a substrate is performed;
a support unit supporting the substrate in the treating space; and
a gas supply unit supplying a process gas for plasma-etching the substrate to the treating space,
wherein the support unit includes:
a body having a lower end provided at a first level, having a step formed at a second level higher than the first level, having an upper end provided at a third level higher than the second level, made of aluminum, and including a first circulation flow passage through which a heat transfer medium circulates and a second circulation flow passage through which a cooling fluid circulates;
a first coating layer formed from the first level to a height of a fourth level higher than the third level so as to surround the body and provided by a thermal spray coating (TSC) method of a ceramic material;
a bonding unit formed from an upper surface of the body to the fourth level and made of silicon;
a second coating layer provided on the first coating layer and provided by atomic layer deposition (ALD) of at least one of aluminum oxide (Al₂O₃) and yttrium oxide (Y₂O₃) so as to have a smaller thickness than the bonding unit and higher hardness and density than the first coating layer;
a puck provided on upper surfaces of the bonding unit and the second coating layer, made of a ceramic material, and having the same radius as the first coating layer; and
a third coating layer provided from a step of the first coating layer formed along the step of the body to an upper end of the puck, having the same hardness and density as the second coating layer, and provided by atomic layer deposition (ALD).
